(19) United States
(12) Patent Application Publication
(10) Pub. No.: US 2026/0282726 A1
(43) Pub. Date: Sep. 17, 2026

(54) DISPLAY DEVICE AND ELECTRONIC DEVICE

(71) Applicant: Samsung Display Co., Ltd., Yongin-si (KR)

(72) Inventors: Hyeon Bum LEE, Yongin-si (KR); Hyoeng Ki KIM, Yongin-si (KR); Hyun Ho KIM, Yongin-si (KR); Eon Joo LEE, Yongin-si (KR)

(21) Appl. No.: 19/381,618

(22) Filed: Nov. 6, 2025

(30) Foreign Application Priority Data
Mar. 13, 2025 (KR) 10-2025-0032570

(51) Int. Cl. H10K 59/80; H10K 59/122; H10K 59/126; H10K 59/38; H10K 59/40; H10K 102/00

(52) U.S. Cl. CPC H10K 59/8792; H10K 59/122; H10K 59/126; H10K 59/38; H10K 59/40; H10K 59/80515; H10K 59/873; H10K 59/879; H10K 2102/351

(57) ABSTRACT

A display device includes: a substrate; a first electrode on the substrate, including a sloped portion and a bottom portion connected from the sloped portion; a pixel definition layer on the substrate and having a first opening exposing the sloped portion and the bottom portion of the first electrode; a light emitting layer on the first electrode exposed through the first opening; a second electrode on the light emitting layer; an encapsulation layer on the second electrode; and a light control layer on the encapsulation layer and including a color filter, a multi-lens pattern, and a light blocking pattern, wherein the multi-lens pattern overlaps the sloped portion in a direction perpendicular to the substrate, wherein the light blocking pattern overlaps the pixel definition layer in a direction perpendicular to the substrate, wherein the multi-lens pattern is within the color filter.

### CROSS-REFERENCE TO RELATED APPLICATION

The present application claims priority to and the benefit of Korean Patent Application No. 10-2025-0032570, filed on Mar. 13, 2025, in the Korean Intellectual Property Office, the entire disclosure of which is incorporated herein by reference.

### BACKGROUND

### 1. Field

Aspects of some embodiments of the present disclosure relate to a display device and an electronic device.

### 2. Description of the Related Art

With the development of the information society, consumer demand for display devices for displaying images is increasing in various forms. For example, display devices may be applied to various electronic devices such as smartphones, digital cameras, notebook computers, navigation devices, and smart televisions.

The display devices may be flat panel display devices such as liquid crystal display devices, field emission display devices, and organic light emitting display devices, and the like. Among these flat panel display devices, light emitting display devices include light emitting elements in which each pixel of the display panel may emit light by itself, so that images may be displayed without a backlight unit that provides light to the display panel.

The above information disclosed in this Background section is only for enhancement of understanding of the background and therefore the information discussed in this Background section does not necessarily constitute prior art.

### SUMMARY

A method for improving the contrast of an organic light emitting display device without using a polarizing film may include forming a light blocking portion and a color filter as an encapsulating layer of the organic light emitting display device to reduce external light reflection. The light blocking portion may include a plurality of openings corresponding to a plurality of pixels, and the color filter may be arranged to overlap the plurality of openings. The organic light emitting display device may be made slim because it does not need to use a polarizing film.

Aspects of some embodiments of the present disclosure include a display device having a relatively improved LvA (side light emission efficiency ratio to front light emission efficiency).

However, aspects of embodiments according to the present disclosure are not restricted to those specifically set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device comprises a substrate, a first electrode arranged on the substrate, including a sloped portion and a bottom portion connected from the sloped portion, a pixel definition layer arranged on the substrate and having a first opening exposing the sloped portion and the bottom portion of the first electrode, a light emitting layer arranged on the first electrode exposed through the first opening, a second electrode arranged on the light emitting layer, an encapsulation layer arranged on the second electrode and a light control layer arranged on the encapsulation layer and including a color filter, a multi-lens pattern, and a light blocking pattern, wherein the multi-lens pattern is arranged to overlap the sloped portion in a direction perpendicular to the substrate, wherein the light blocking pattern is arranged to overlap the pixel definition layer in a direction perpendicular to the substrate, wherein the multi-lens pattern is arranged within the color filter.

According to some embodiments, a thickness of the multi-lens pattern is thicker than a thickness of the light blocking pattern and thinner than a thickness of the color filter.

According to some embodiments, a refractive index of the multi-lens pattern is lower than a refractive index of the encapsulation layer and lower than a refractive index of the color filter.

According to some embodiments, the refractive index of the multi-lens pattern is 1.5 or less.

According to some embodiments, the multi-lens pattern includes a plurality of lenses having a shape in which the top surface is convex upward.

According to some embodiments, the multi-lens pattern includes a first lens portion including a plurality of lenses having a center arranged on a first outer periphery, and a second lens portion including a plurality of lenses having a center on a second outer periphery, wherein the first outer periphery and the second outer periphery are concentric outer peripheries, and a diameter of the second outer periphery is larger than a diameter of the first outer periphery.

According to some embodiments, the first lens portion surrounds the bottom portion on a plane, and wherein the second lens portion surrounds the first lens portion on a plane.

According to some embodiments, each of the plurality of lenses included in the first lens portion has a first curvature, and each of the plurality of lenses included in the second lens portion has a second curvature, wherein the first curvature and the second curvature are different.

According to some embodiments, the multi-lens pattern is further arranged in an outer area, wherein the outer area overlaps the pixel definition layer in a direction perpendicular to the substrate but does not overlap the light blocking pattern and the sloped portion.

According to some embodiments, the multi-lens pattern comprises a first lens portion including a plurality of lenses that overlap with a sloped portion of the first electrode in a direction perpendicular to the substrate and surround the bottom portion, a second lens portion including a plurality of lenses that overlap with a sloped portion of the first electrode in a direction perpendicular to the substrate and surround the first lens portion, and a third lens portion including a plurality of lenses that are arranged at least partially in the outer area and surround the second lens portion.

According to some embodiments, the light blocking pattern has a second opening having a width greater than a width of the first opening and overlapping the first opening, wherein the multi-lens pattern is arranged in the second opening, wherein the color filter covers the multi-lens pattern and the second opening.

According to some embodiments, the display device further comprises a first overcoat layer arranged between the encapsulation layer and the light control layer and a touch electrode layer arranged between the first overcoat layer and the light control layer, wherein the touch electrode layer includes a touch electrode, wherein the touch electrode overlaps the light blocking pattern in a direction perpendicular to the substrate.

According to some embodiments, the pixel definition layer includes a light blocking material.

According to some embodiments, the display device further comprises a via layer arranged on the substrate, wherein the via layer includes a first via layer having a sloped corresponding to a sloped of the first electrode, and a second via layer arranged below the first via layer and including a surface corresponding to a bottom portion of the first electrode.

According to some embodiments, the first via layer and the second via layer are different layers, or wherein the first via layer and the second via layer are a single via layer formed integrally.

According to some embodiments of the present disclosure, a display device comprises a substrate, a first electrode arranged on the substrate, including a sloped portion and a bottom portion connected from the sloped portion, a pixel definition layer arranged on the substrate and having a first opening exposing the sloped portion and the bottom portion of the first electrode, a light emitting layer arranged on the first electrode exposed through the first opening, second electrode arranged on the light emitting layer, an encapsulation layer arranged on the second electrode and a light control layer arranged on the encapsulation layer and including a color filter, a multi-lens pattern, and a light blocking pattern, wherein the multi-lens pattern includes a plurality of lenses that are convex upward and surrounds the bottom portion on a plane, wherein the light blocking pattern surrounds the multi-lens pattern on the same plane as the multi-lens pattern, wherein the color filter covers the multi-lens pattern.

According to some embodiments, a thickness of the multi-lens pattern is thicker than a thickness of the light blocking pattern and thinner than a thickness of the color filter.

According to some embodiments, a refractive index of the multi-lens pattern is lower than a refractive index of the encapsulation layer and a refractive index of the color filter, wherein the refractive index of the multi-lens pattern is 1.5 or less.

According to some embodiments, the display device further comprises a first overcoat layer arranged on the encapsulation layer and a touch electrode layer arranged on the first overcoat layer, wherein the touch electrode layer includes a touch electrode, and wherein the touch electrode overlaps the light blocking pattern.

According to some embodiments of the present disclosure, a electronic device comprises a display panel for displaying an image, wherein the display panel includes, a substrate, a first electrode arranged on the substrate, including a sloped portion and a bottom portion connected from the sloped portion, a pixel definition layer arranged on the substrate and having a first opening exposing the sloped portion and the bottom portion of the first electrode, a light emitting layer arranged on the first electrode exposed through the first opening, a second electrode arranged on the light emitting layer, an encapsulation layer arranged on the second electrode and a light control layer arranged on the encapsulation layer and including a color filter, a multi-lens pattern, and a light blocking pattern, wherein the multi-lens pattern is arranged to overlap the sloped portion in a direction perpendicular to the substrate, and wherein the light blocking pattern is arranged to overlap the pixel definition layer in a direction perpendicular to the substrate, wherein the multi-lens pattern is arranged within the color filter.

According to some embodiments, a display device according to some embodiments may have relatively improved LvA (side light emission efficiency ratio to front light emission efficiency).

However, aspects of embodiments according to the present disclosure are not limited to the aforementioned aspects, and various other aspects are included in the present specification.

### BRIEF DESCRIPTION OF THE DRAWINGS

FIG. 1 is a schematic perspective view of an electronic device according to some embodiments.

FIG. 2 is a perspective view illustrating a display device included in an electronic device according to some embodiments.

FIG. 3 is a cross-sectional view of the display device of FIG. 2 from the side.

FIG. 4 is a plan view illustrating a display layer of a display device according to some embodiments.

FIG. 5 is a plan view illustrating a touch sensing layer of a display device according to some embodiments.

FIG. 6 is an enlarged view of area A1 of FIG. 5.

FIG. 7 is a cross-sectional view illustrating a first light emitting area of a display panel according to some embodiments.

FIG. 8 is an enlarged view of area A of FIG. 7.

FIG. 9 is a cross-sectional view illustrating the arrangement of components adjacent to the lens pattern of FIG. 8.

FIG. 10 is an enlarged view of area A of FIG. 7 according to some embodiments.

FIG. 11 is a cross-sectional view illustrating the arrangement of components adjacent to the lens pattern of FIG. 10.

FIG. 12 is an enlarged view of area A of FIG. 7 according to some embodiments.

FIG. 13 is a cross-sectional view illustrating the arrangement of components adjacent to the lens pattern of FIG. 10.

FIG. 14 is a graph to illustrate light refraction characteristics as a function of lens thickness.

FIG. 15 is a conceptual diagram to illustrate the effect of relatively improving LvA (the ratio of side light emission efficiency to front light emission efficiency) in the embodiments of FIG. 10.

FIG. 16 is a conceptual diagram to illustrate the effect of relatively improving LvA (the ratio of side light emission efficiency to front light emission efficiency) in the embodiments of FIG. 12.

FIGS. 17 to 19 are cross-sectional views to illustrate a process for manufacturing a display device according to some embodiments.

FIG. 20 is a block diagram of an electronic device according to some embodiments of the present disclosure

FIG. 21 is a schematic diagram of an electronic device according to some embodiments of the present disclosure

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be more thorough and more complete, and will more fully convey the aspects and features of embodiments according to the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

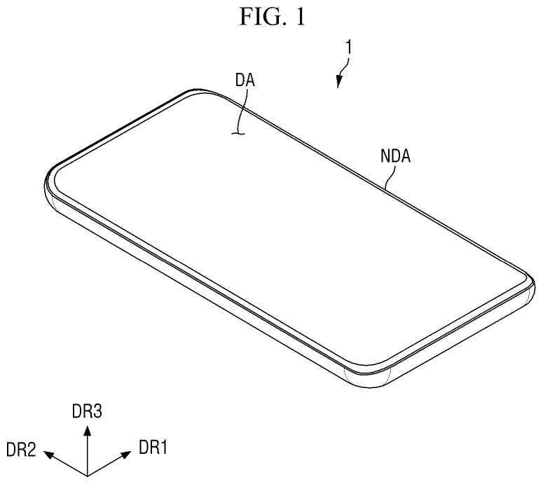

FIG. 1 is a schematic perspective view of an electronic device according to some embodiments.

Referring to FIG. 1, an electronic device 1 displays a moving image or a still image. The electronic device 1 may refer to any electronic device that provides a display screen. For example, the electronic device 1 may include a television, a laptop, a monitor, a billboard, an Internet of Things, a mobile phone, a smart phone, a tablet personal computer (PC), an electronic watch, a smart watch, a watch phone, a head-mounted display, a mobile communication terminal, an electronic notebook, an electronic book, a portable multimedia player (PMP), a navigation system, a game console, a digital camera, a camcorder, etc. that provide a display screen.

In FIG. 1, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. The first direction DR1 refers to a horizontal direction in the drawing, the second direction DR2 refers to a vertical direction in the drawing, and the third direction DR3 means upper and lower directions, i.e. a thickness direction. In the following disclosure, unless otherwise specified, “direction” may refer to both directions extending along that direction. Furthermore, when it is necessary to distinguish between the two “directions” extending to both sides, one side is referred to as “direction one side” and the other side is referred to as “direction other side”, respectively. With reference to FIG. 1, the direction in which the arrow indicating the direction is pointing is referred to as one side, and the opposite direction is referred to as the other side.

Hereinafter, for the convenience of explanation, when referring to the surfaces of the electronic device 1 or each member constituting the electronic device 1, the surface facing the direction in which the image is displayed, i.e. the third direction DR3, is referred to as the top surface, and the surface opposite to the one surface is referred to as the bottom surface. However, embodiments according to the present disclosure are not limited thereto, and the one side and the other side of the above-mentioned absence may be referred to as the front side and the back side, respectively, or may be referred to as the first side or the second side. Also, when explaining the relative positions of each of the members of the electronic device 1_9, one side in the third direction DR3 may be referred to as the upper side, and the other side in the third direction DR3 may be referred to as the lower side.

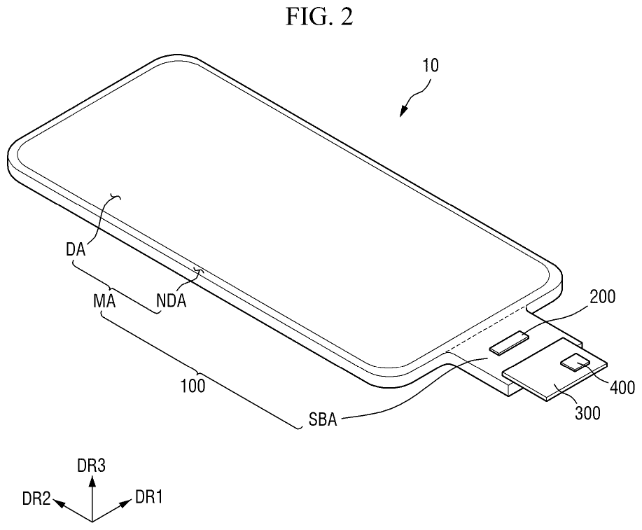

The electronic device 1 may include a display device (‘10’ in FIG. 2) that provides a display screen. Examples of the display device may include an inorganic light-emitting diode display device, an organic light-emitting display device, a quantum dot light-emitting display device, a plasma display device, a field emission display device, and the like. Hereinafter, as an example of a display device, an organic light-emitting diode display device is applied, but embodiments according to the present disclosure are not limited thereto, and if the same technical idea is applicable, it may be applied to other display devices.

The shape of the electronic device 1 may be modified in various ways. For example, the electronic device 1 may have a shape such as a long rectangle, a long rectangle, a square, a square with rounded corners (vertices), other polygons, circles, or the like. The shape of the display area DA of the electronic device 1 may also be similar to the overall shape of the electronic device 1. In FIG. 1, the electronic device 1 is illustrated in a rectangular shape with an elongated length in the second direction DR2.

The electronic device 1 may include a display area DA and a non-display area NDA. The display area DA is an area where a screen may be displayed, and the non-display area NDA is an area where a screen is not displayed. The display area DA may be referred to as an active area, and the non-display area NDA may also be referred to as an inactive area. The display area DA may generally occupy the center of the electronic device 1.

FIG. 2 is a perspective view illustrating a display device included in an electronic device according to some embodiments.

Referring to FIG. 2, an electronic device 1 according to some embodiments may include a display device 10. The display device 10 may provide a screen displayed on the electronic device 1. The display device 10 may have a similar planar shape to the electronic device 1. For example, the display device 10 may have a shape similar to a rectangle having a short side in a first direction DR1 and a long side in a second direction DR2. The corner where the short side in the first direction DR1 and the long side in the second direction DR2 meet may be formed to have a rounded shape to have a curvature but is not limited thereto and may be formed at a right angle. The planar shape of the display device 10 is not limited to a square and may be formed similarly to other polygons, circles, or ovals.

The display device 10 may include a display panel 100, a display driving portion 200, a circuit board 300, and a touch driving portion 400.

The display panel 100 may include a main area MA and a sub-area SBA.

The main area MA may include a display area DA including pixels displaying an image, and a non-display area NDA arranged around (e.g., in a periphery or outside a footprint of) the display area DA. The display area DA may emit light from a plurality of light emitting areas or a plurality of opening areas described below. For example, the display panel 100 may include a pixel circuit including switching elements, a pixel definition film defining a light emitting area or an opening area, and a self-light emitting element.

For example, the self-light emitting element may include at least one of an organic light emitting diode (OLED) including an organic light emitting layer, a quantum dot LED including a quantum dot light emitting layer, an inorganic LED including an inorganic semiconductor, or a micro light emitting diode (Micro LED), but embodiments according to the present disclosure are not limited thereto. In the following drawings, the self-light emitting element is illustrated as an organic light emitting diode.

The non-display area NDA may be an outer area of the display area DA. The non-display area NDA may be defined as an edge area of the main area MA of the display panel 100. The non-display area NDA may include a gate driving portion that supplies gate signals to gate lines, and fan-out lines that connect the display driving portion 200 and the display area DA.

The sub-area SBA may be an area extending from one side of the main area MA. The sub-area SBA may include a flexible material that is capable of bending, folding, rolling, and the like. For example, when the sub-area SBA_9 is bent, the sub-area SBA_9 may overlap the main area MA in the thickness direction (the third direction DR3). The sub-area SBA may include a display driving portion 200 and a pad portion connected to the circuit board 300. According to some embodiments, the sub-area SBA may be omitted, and the display driving portion 200 and the pad portion may be placed in the non-display area NDA.

The display driving portion 200 may output signals and voltages for driving the display panel 100. The display driving portion 200 may supply data voltages to data lines. The display driving portion 200 may supply a power voltage to a power supply line and may supply a gate control signal to the gate driving portion. The display driving portion 200 may be formed as an integrated circuit (IC) and mounted on the display panel 100 using a chip on glass (COG) method, a chip on plastic (COP) method, or an ultrasonic bonding method. For example, the display driving portion 200 may be arranged in the sub-area SBA and may overlap the main area MA in the thickness direction by bending the sub-area SBA. In another example, the display driving portion 200 may be mounted on a circuit board 300.

The circuit board 300 may be attached to the pad portion of the display panel 100 using an anisotropic conductive film (ACF). The lead lines of the circuit board 300 may be electrically connected to the pad portion of the display panel 100. The circuit board 300 may be a flexible film such as a flexible printed circuit board, a printed circuit board, or a chip on film.

The touch driving portion 400 may be mounted on the circuit board 300. The touch driving portion 400 may be connected to the touch sensing unit of the display panel 100. The touch driving portion 400 may supply a touch driving signal to a plurality of touch electrodes of the touch sensing portion and may sense a change in electrostatic capacitance between the plurality of touch electrodes. For example, the touch driving signal may be a pulse signal having a frequency (e.g., a set or predetermined frequency). The touch driving portion 400 may calculate whether an input has occurred and input coordinates based on the change in electrostatic capacitance between the plurality of touch electrodes. The touch driving portion 400 may be formed as an integrated circuit (IC).

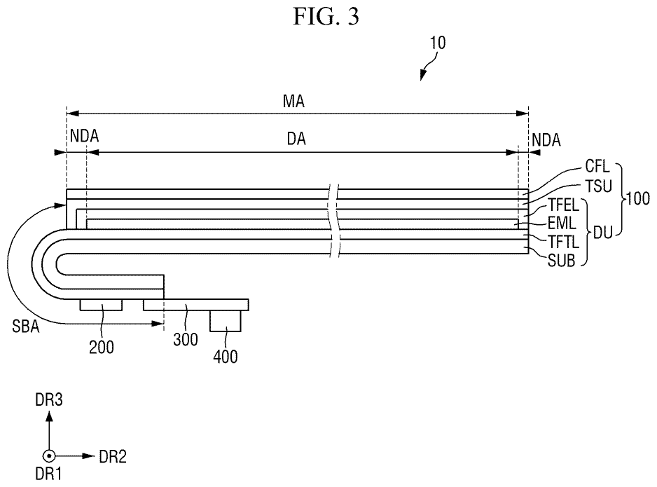

FIG. 3 is a cross-sectional view of the display device of FIG. 2 from the side.

Referring to FIG. 3, the display panel 100 may include a display layer DU, a touch electrode layer TSL, and a light control layer CFL. The display layer DU may include a substrate SUB, a thin-film transistor layer TFTL, a light emitting element layer EML, and an encapsulation layer TFEL.

The substrate SUB may be a base substrate or a base member. The substrate SUB may be a flexible substrate capable of bending, folding, rolling, and the like. For example, the substrate SUB may include a polymer resin such as polyimide (PI) but embodiments according to the present disclosure are not limited thereto. According to some embodiments, the substrate SUB may include a glass material or a metal material.

The thin-film transistor layer TFTL may be arranged on the substrate SUB. The thin-film transistor layer TFTL may include a plurality of thin-film transistors that constitute a pixel circuit of pixels. The thin-film transistor layer TFTL may further include gate lines, data lines, power supply lines, gate control lines, fan-out lines connecting the display driving portion 200 and the data lines, and lead lines connecting the display driving portion 200 and the pad portion. Each of the thin-film transistors may include a semiconductor area, a source electrode, a drain electrode, and a gate electrode. For example, when the gate driving portion is formed on one side of the non-display area NDA of the display panel 100, the gate driving portion may include thin-film transistors.

The thin-film transistor layer TFTL may be arranged in the display area DA, the non-display area NDA, and the sub-area SBA. The thin-film transistors, gate lines, data lines, and power supply lines of each pixel of the thin-film transistor layer TFTL may be arranged in the display area DA. The gate control lines and fan-out lines of the thin-film transistor layer TFTL may be arranged in the non-display area NDA. The lead lines of the thin-film transistor layer TFTL may be arranged in the sub-area SBA.

The light emitting element layer EML may be arranged on the thin-film transistor layer TFTL. The light emitting element layer EML may include a plurality of light emitting elements that emit light, including a first electrode, a second electrode, and an emission layer, and a pixel definition film that defines pixels. The plurality of light emitting elements of the light emitting element layer EML may be arranged in the display area DA.

According to some embodiments, the light emitting layer may be an organic light emitting layer including an organic material. The light emitting layer may include a hole transporting layer, an organic light emitting layer, and an electron transporting layer. When the first electrode receives a voltage through the thin-film transistor of the thin-film transistor layer TFTL, and the second electrode receives a cathode voltage, holes and electrons may move to the organic light emitting layer through the hole transporting layer and the electron transporting layer, respectively, and may combine with each other in the organic light emitting layer to emit light.

According to some embodiments, the light emitting element may include a quantum dot light emitting diode including a quantum dot light emitting layer, an inorganic light emitting diode including an inorganic semiconductor, or a micro light emitting diode.

The encapsulation layer TFEL may cover the top surface and the side surface of the light emitting element layer EML and may protect the light emitting element layer EML. According to some embodiments, the encapsulation layer TFEL may include at least one inorganic film and at least one organic film for encapsulating the light emitting element layer EML.

The touch electrode layer TSL may be arranged on the encapsulation layer TFEL. The touch electrode layer TSL may include a plurality of touch electrodes for detecting a user's touch in a capacitive manner, and touch lines connecting the plurality of touch electrodes and the touch driving portion 400. For example, the touch electrode layer TSL may sense a user's touch in a mutual capacitance manner or a self-capacitance manner.

According to some embodiments, the touch electrode layer TSL may be arranged on a separate substrate arranged on the display layer DU. In this case, the substrate supporting the touch electrode layer TSL may be a base member encapsulating the display layer DU.

The plurality of touch electrodes of the touch electrode layer TSL may be arranged in a touch sensor area overlapping the display area DA. The touch lines of the touch electrode layer TSL may be arranged in a touch peripheral area overlapping the non-display area NDA.

The light control layer CFL may be arranged on the touch electrode layer TSL. The light control layer CFL may include a plurality of color filters corresponding to each of the plurality of light emitting areas. Each of the color filters may selectively transmit light of a specific wavelength and block or absorb light of a different wavelength. The light control layer CFL may absorb a portion of light entering from the outside of the display device 10 to reduce reflected light due to external light. Thus, the light control layer CFL may prevent or reduce color distortion due to external light reflection.

Because the light control layer CFL is directly arranged on the touch electrode layer TSL, the display device 10 may not require a separate substrate for the light control layer CFL. Accordingly, the thickness of the display device 10 may be relatively small.

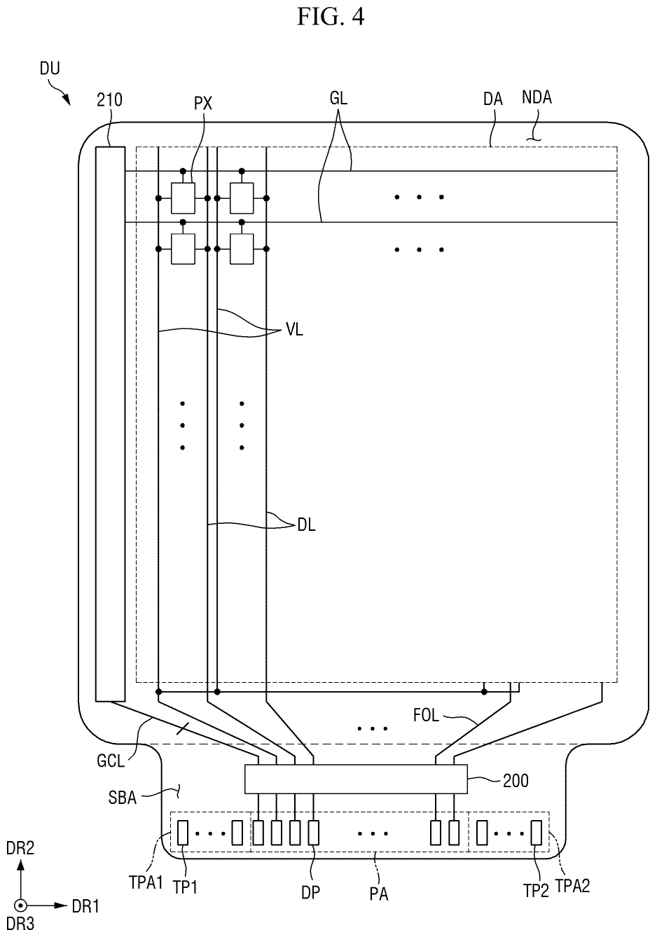

FIG. 4 is a plan view illustrating a display layer of a display device according to some embodiments.

Referring to FIG. 4, the display layer DU may include a display area DA and a non-display area NDA.

The display area DA may be arranged at the center of the display panel 100. A plurality of pixels PX, a plurality of gate lines GL, a plurality of data lines DL, and a plurality of power supply lines VL may be arranged in the display area DA. Each of the plurality of pixels PX may be defined as a minimum unit that emits light.

The plurality of gate lines GL may supply a gate signal received from the gate driving portion 210 to the plurality of pixels PX. The plurality of gate lines GL may extend in a first direction DR1 and may be spaced apart from each other (e.g., in a plan view) in a second direction DR2 intersecting the first direction DR1.

The display device 10 according to some embodiments may further include light emitting wires that provide a voltage required for light emission of each pixel PX. The above-described light emitting wires may extend in a first direction DR1 and may be spaced apart from each other in a second direction DR2 intersecting the first direction DR1 and may supply light emitting signals received from the gate driving portion 210 to a plurality of pixels PX.

The plurality of data lines DL may supply data voltages received from the display driving portion 200 to the plurality of pixels PX. The plurality of data lines DL may extend in the second direction DR2 and may be spaced apart from each other in the first direction DR1.

The plurality of power supply lines VL may supply power voltages received from the display driving portion 200 to the plurality of pixels PX. The power voltage may be at least one of a driving voltage, an initialization voltage, a reference voltage, or a low-potential voltage. The plurality of power supply lines VL may extend in the second direction DR2 and may be spaced apart from each other (e.g., in a plan view) in the first direction DR1.

The non-display area NDA may surround a display area DA. A gate driving portion 210, fan-out lines FOL, and gate control lines GCL may be arranged in the non-display area NDA. The gate driving portion 210 may generate a plurality of gate signals based on a gate control signal and may sequentially supply the plurality of gate signals to a plurality of gate lines GL in a set order.

The fan-out lines FOL may extend from the display driving portion 200 to the display area DA. The fan-out lines FOL may supply a data voltage received from the display driving portion 200 to a plurality of data lines DL.

The gate control line GCL may extend from the display driving portion 200 to the gate driving portion 210. The gate control line GCL may supply a gate control signal received from the display driving portion 200 to the gate driving portion 210. (It is suggested that a light emitting driving portion may be further illustrated to distinguish it from a conventional LCD driving portion, or that a light emitting driving portion may be added to the detailed description of the disclosure.)

The sub-area SBA may include the display driving portion 200, the pad area PA, and the first and second touch pad areas TPA1 and TPA2.

The display driving portion 200 may output signals and voltages for driving the display panel 100 to the fan-out lines FOL. The display driving portion 200 may supply a data voltage to the data line DL through the fan-out lines FOL. The data voltage may be supplied to a plurality of pixels PX and may control the brightness of the plurality of pixels PX. The display driving portion 200 may supply a gate control signal to the gate driving portion 210 through the gate control line GCL.

The pad area PA, the first touch pad area TPA1, and the second touch pad area TPA2 may be arranged at the edge of the sub-area SBA_9. The pad area PA, the first touch pad area TPA1, and the second touch pad area TPA2 may be electrically connected to the circuit board 300 using a material such as an anisotropic conductive film or a self-assembly anisotropic conductive paste (SAP).

The pad area PA may include a plurality of display pad portions DP. The plurality of display pad portions DP may be connected to the graphic system through the circuit board 300. The plurality of display pad portions DP may be connected to the circuit board 300 to receive digital video data and supply the digital video data to the display driving portion 200.

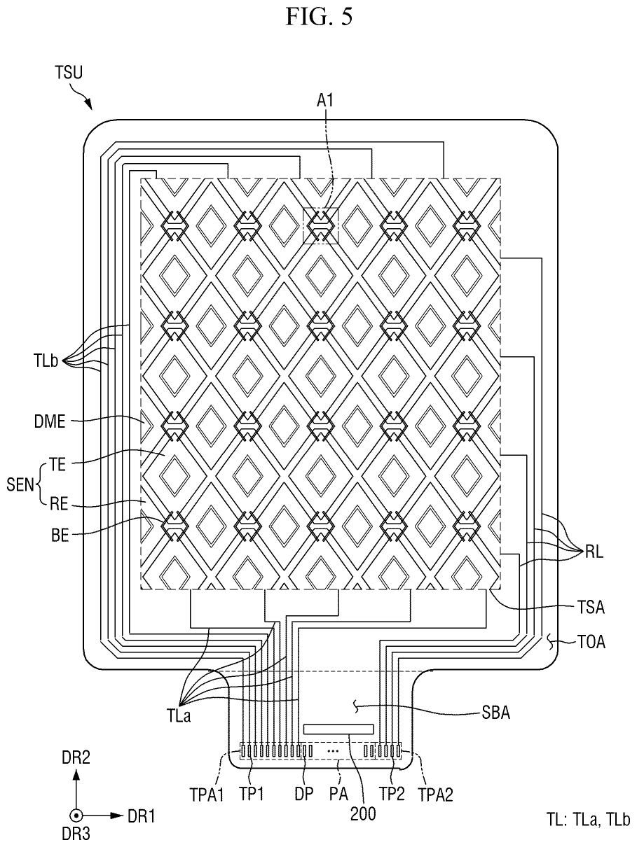

FIG. 5 is a plan view illustrating a touch sensing layer of a display device according to some embodiments.

Referring to FIG. 5, the touch electrode layer TSL may include a touch sensor area TSA that detects a user's touch, and a touch peripheral area TOA arranged around the touch sensor area TSA. The touch sensor area TSA may be arranged in a display area DA of the display device 10, and the touch peripheral area TOA may be arranged in a non-display area NDA of the display device 10.

The touch sensor area TSA may include a plurality of touch electrodes SEN and a plurality of dummy electrodes DME. The plurality of touch electrodes SEN may form mutual capacitance or self-capacitance to detect a touch of an object or a person. The plurality of touch electrodes SEN may include a plurality of driving electrodes TE and a plurality of sensing electrodes RE.

The plurality of driving electrodes TE may be arranged in a first direction DR1 and a second direction DR2. The plurality of driving electrodes TE may be spaced apart from each other in the first direction DR1 and the second direction DR2. The driving electrodes TE adjacent to each other in the second direction DR2 may be electrically connected through a bridge electrode BE.

The plurality of driving electrodes TE may be connected to the first touch pad portion TP1 through a driving line TDL. The driving line TDL may include a lower driving line TLa and an upper driving line TLb. For example, the driving electrodes TE arranged on the lower side of the touch sensor area TSA may be connected to the first touch pad portion TP1 through the lower driving line TLa, and the driving electrodes TE arranged on the upper side of the touch sensor area TSA may be connected to the first touch pad portion TP1 through the upper driving line TLb. The lower driving line TLa may extend through the lower side of the touch peripheral area TOA to the first touch pad portion TP1. The upper driving line TLb may extend to the first touch pad portion TP1 through the upper side, the left side, and the lower side of the touch peripheral area TOA. The first touch pad portion TP1 may be connected to the touch driving portion 400 through the circuit board 300.

The bridge electrode BE may be bent at least once. For example, the bridge electrode BE may have a bracket shape (“<” or “>”), but the planar shape of the bridge electrode BE is not limited thereto. The driving electrodes TE adjacent to each other in the second direction DR2 may be connected by a plurality of bridge electrodes BE, and even if one of the bridge electrodes CE is disconnected, the driving electrodes TE may be stably connected through the remaining bridge electrodes BE. The driving electrodes TE adjacent to each other may be connected by two bridge electrodes BE, but the number of bridge electrodes CE is not limited thereto.

The bridge electrode BE may be arranged in different layers from the plurality of driving electrodes TE and the plurality of sensing electrodes RE. The sensing electrodes RE adjacent to each other in the first direction DR1 may be electrically connected through a connecting portion arranged in the same layer as the plurality of driving electrodes TE or the plurality of sensing electrodes RE, and the driving electrodes TE adjacent to each other in the second direction DR2 may be electrically connected to the plurality of driving electrodes TE or the plurality of sensing electrodes RE through a bridge electrode BE arranged in a different layer from each other. Accordingly, even if the bridge electrode BE overlaps the plurality of sensing electrodes RE in the Z-axis direction, the plurality of driving electrodes TE and the plurality of sensing electrodes RE may be insulated from each other. Mutual capacitance may be formed between the driving electrodes TE and the sensing electrodes RE.

The plurality of sensing electrodes RE may extend in the first direction DR1 and be spaced apart from each other in the second direction DR2. The plurality of sensing electrodes RE may be arranged in the first direction DR1 and the second direction DR2, and sensing electrodes RE adjacent in the first direction DR1 may be electrically connected through a connection portion.

The plurality of sensing electrodes RE may be connected to a second touch pad portion TP2 through a sensing line RL. For example, sensing electrodes RE arranged on the right side of the touch sensor area TSA may be connected to the second touch pad portion TP2 through the sensing line RL. The sensing line RL may extend to the second touch pad portion TP2 through the right side and the lower side of the touch peripheral area TOA. The second touch pad portion TP2 may be connected to the touch driving portion 400 through the circuit board 300.

Each of the plurality of dummy electrodes DME may be surrounded by a driving electrode TE or a sensing electrode RE. Each of the plurality of dummy electrodes DME may be separated from and insulated from the driving electrode TE or the sensing electrode RE. Thus, the dummy electrode DME may be electrically floated.

The pad area PA, the first touch pad area TPA1, and the second touch pad area TPA2 may be arranged at the edge of the sub-area SBA_9. The pad area PA, the first touch pad area TPA1, and the second touch pad area TPA2 may be electrically connected to the circuit board 300 using a low-resistance, high-reliability material such as an anisotropic conductive film or a self-assembly anisotropic conductive paste (SAP).

The first touch pad area TPA1 may be arranged at one side of the pad area PA and may include a plurality of first touch pad portions TP1. The plurality of first touch pad portions TP1 may be electrically connected to the touch driving portion 400 arranged on the circuit board 300. The plurality of first touch pad portions TP1 may supply touch driving signals to a plurality of driving electrodes TE through a plurality of driving lines TDL.

The second touch pad area TPA2 may be arranged on the other side of the pad area PA and may include a plurality of second touch pad portions TP2. The plurality of second touch pad portions TP2 may be electrically connected to the touch driving portion 400 arranged on the circuit board 300. The touch driving portion 400 may receive touch sensing signals through a plurality of sensing lines RL connected to the plurality of second touch pad portions TP2 and may sense a change in mutual electrostatic capacity between the driving electrodes TE and the sensing electrodes RE.

According to some embodiments, the touch driving portion 400 may supply touch driving signals to each of the plurality of driving electrodes TE and the plurality of sensing electrodes RE and may receive touch sensing signals from each of the plurality of driving electrodes TE and the plurality of sensing electrodes RE. The touch driving portion 400 may sense a change in charge of each of the plurality of driving electrodes TE and the plurality of sensing electrodes RE based on a touch sensing signal.

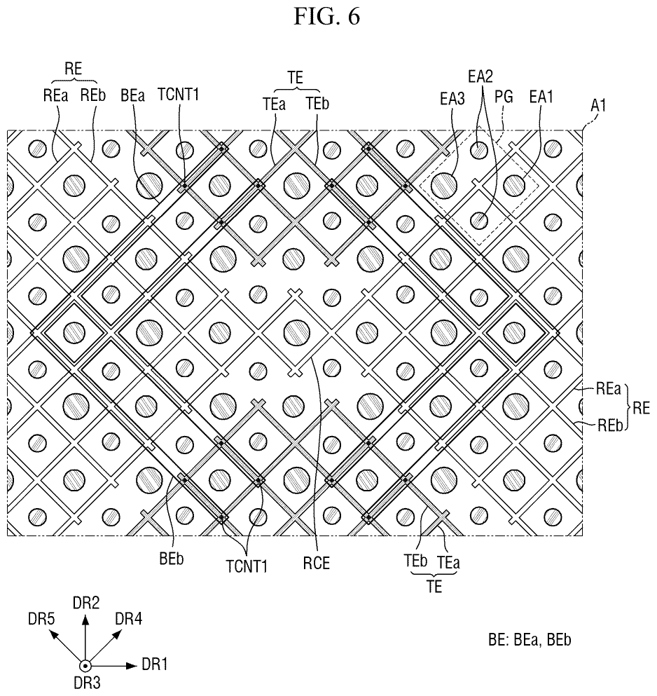

FIG. 6 is an enlarged view of the area A1 of FIG. 5.

Referring to FIG. 6, the touch electrode layer TSL may include a plurality of driving electrodes TE, a plurality of sensing electrodes RE, and a plurality of dummy electrodes DME as touch electrodes, which may be arranged on the same layer and spaced apart from each other. The touch electrode layer TSL may also include a plurality of bridge electrodes BE arranged below the plurality of driving electrodes TE, the plurality of sensing electrodes RE, and the plurality of dummy electrodes DME.

The plurality of driving electrodes TE may be arranged in a first direction DR1 and a second direction DR2. The plurality of driving electrodes TE may be spaced apart from each other in the first direction DR1 and the second direction DR2. The driving electrodes TE adjacent in the second direction DR2 may be electrically connected through the bridge electrodes BE.

The plurality of sensing electrodes RE may extend in the first direction DR1 and be spaced apart from each other in the second direction DR2. The plurality of sensing electrodes RE may be arranged in the first direction DR1 and the second direction DR2, and sensing electrodes RE adjacent in the first direction DR1 may be electrically connected through a connecting portion RCE. For example, the connecting portion RCE of the sensing electrodes RE may be arranged within the shortest distance of the adjacent driving electrodes TE.

The plurality of bridge electrodes BE may be arranged in a different layer from the driving electrodes TE and the sensing electrodes RE. The bridge electrode BE may include a first portion BEa and a second portion BEb. For example, the first portion BEa of the bridge electrode BE may be connected to the driving electrode TE arranged on one side through a first touch contact hole TCNT1 and may extend in the third direction DR3. A second portion BEb of the bridge electrode BE may be bent from the first portion BEa in an area overlapping the sensing electrode RE and may extend in a second direction DR2 and may be connected to a driving electrode TE arranged on the other side through the first touch contact hole TCNT1. Accordingly, each of the plurality of bridge electrodes BE may electrically connect adjacent driving electrodes TE in the second direction DR2.

On the other hand, a fourth direction DR4 and a fifth direction DR5 are additionally defined in FIG. 6. The fourth direction DR4 may be a direction between one side of the first direction DR1 and one side of the second direction DR2, and the fifth direction DR5 may be a direction between the other side of the first direction DR1 and one side of the second direction DR2.

Each of the plurality of driving electrodes TE may include a first portion TEa extending in the fourth direction DR4 and a second portion TEb extending in the fifth direction DR5. Each of the plurality of sensing electrodes RE may include a first portion REa extending in the fourth direction DR4 and a second portion REb extending in the fifth direction DR5.

According to some embodiments, the plurality of driving electrodes TE, the plurality of sensing electrodes RE, and the plurality of dummy electrodes DME may be formed in a planar mesh structure or a mesh structure. The plurality of driving electrodes TE, the plurality of sensing electrodes RE, and the plurality of dummy electrodes (DME) may surround the first to third emission areas EA1, EA2, and EA3 of the pixel group PG on the planar surface, respectively. Thus, the plurality of driving electrodes TE, the plurality of sensing electrodes RE, and the plurality of dummy electrodes DME may not overlap the first to third emission areas EA1, EA2, and EA3. The plurality of bridge electrodes BE may also not overlap with the first to third light emitting areas EA1, EA2, and EA3. Therefore, the display device 10 may prevent or reduce the brightness of light emitted from the first to third light emitting areas EA1, EA2, and EA3 being reduced by the touch electrode layer TSL.

The plurality of pixels may include first to third pixels, and each of the first to third pixels may include first to third light emitting areas EA1, EA2, and EA3. For example, the first light emitting area EA1 may emit light of a first color or blue light, the second light emitting area EA2 may emit light of a second color or green light, and the third light emitting area EA3 may emit light of a third color or red light but is not limited thereto.

One pixel group PG may express white gradation by including one first light emitting area EA1, two second light emitting areas EA2, and one third light emitting area EA3, but the configuration of the pixel group PG is not limited thereto. White gradation may be expressed by a combination of light emitted from the first light emitting area EA1, light emitted from the second light emitting area EA2, and light emitted from the third light emitting area EA3.

The sizes of the first to third light emitting areas EA1, EA2, and EA3 may be different from each other. For example, the size of the first light emitting area EA1 may be larger than the size of the third light emitting area EA3, and the size of the third light emitting area EA3 may be larger than the size of the second light emitting area EA2 but is not limited thereto. According to some embodiments, the sizes of the first to third light emitting areas EA1, EA2, and EA3 may be the same.

In FIG. 6, the planar shape of the first to third light emitting areas EA1, EA2, and EA3 is illustrated as being circular but is not limited thereto. According to some embodiments, the planar shape of the first to third light emitting areas EA1, EA2, and EA3 may be generally octagonal. According to some embodiments, the planar shape of the first to third light emitting areas EA1, EA2, and EA3 may be a rhombus or other polygon, a polygon with rounded corners, or the like.

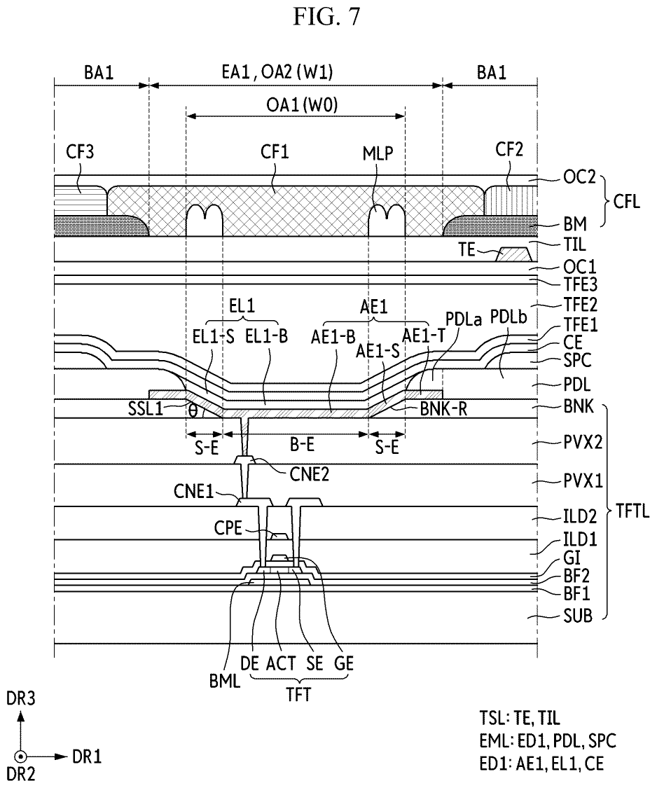

FIG. 7 is a cross-sectional view illustrating a first light emitting area of a display panel according to some embodiments.

According to some embodiments, referring to FIG. 7, the first light emitting area EA1 is described, but the second light emitting area EA2 and the third light emitting area EA3 also have similar structures.

Referring to FIG. 7, the substrate SUB is omitted for detailed description as described above.

The thin-film transistor layer TFTL may include a first buffer layer BF1, a bottom metal layer BML, a second buffer layer BF2, a thin-film transistor TFT, a gate insulating layer GI, a first interlayer insulating layer ILD1, a capacitor electrode CPE, a second interlayer insulating layer ILD2, a first connection electrode CNE1, a first protective layer PVX1, a second connection electrode CNE2, a second protective layer PVX2, and a bank layer BNK.

The first buffer layer BF1 may be arranged on the substrate SUB. The first buffer layer BF1 may include an inorganic film capable of preventing or reducing the penetration of contaminants such as air or moisture. For example, the first buffer layer BF1 may include a plurality of inorganic films alternately laminated.

The bottom metal layer BML may be arranged on the first buffer layer BF1. For example, the bottom metal layer BML may be formed as a single layer or multiple layers made of one of molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the bottom metal layer BML. The second buffer layer BF2 may include an inorganic film capable of preventing or reducing the penetration of contaminants such as air or moisture. For example, the second buffer layer BF2 may include a plurality of inorganic films alternately laminated.

The thin-film transistor TFT may be arranged on the second buffer layer BF2 and may constitute a pixel circuit of each of a plurality of pixels. For example, the thin-film transistor TFT may be a driving transistor or a switching transistor of the pixel circuit. The thin-film transistor TFT may include a semiconductor layer ACT, a source electrode SE, a drain electrode DE, and a gate electrode GE.

The semiconductor layer ACT may be arranged on the second buffer layer BF2. The semiconductor layer ACT may overlap with the bottom metal layer BML and the gate electrode GE in a direction and may be insulated from the gate electrode GE by a gate insulating layer GI. A portion of the semiconductor layer ACT may be a material of the semiconductor layer ACT that is conductive to form the source electrode SE and the drain electrode DE.

The gate electrode GE may be arranged on the gate insulating layer GI. The gate electrode GE may overlap with the semiconductor layer ACT with the gate insulating layer GI between them.

The gate insulating layer GI may be arranged on the semiconductor layer ACT. For example, the gate insulating layer GI may cover the semiconductor layer ACT, the source electrode SE, the drain electrode DE, and the second buffer layer BF2, and may insulate the semiconductor layer ACT and the gate electrode GE. The gate insulating layer GI may include a contact hole through which the first connection electrode CNE1 penetrates.

The first interlayer insulating layer ILD1 may cover the gate electrode GE and the gate insulating layer GI. The first interlayer insulating layer ILD1 may include a contact hole through which the first connection electrode CNE1 penetrates. The contact hole of the first interlayer insulating layer ILD1 may be connected to the contact hole of the gate insulating layer GI and the contact hole of the second interlayer insulating layer ILD2.

The capacitor electrode CPE may be arranged on the first interlayer insulating layer ILD1. The capacitor electrode CPE may overlap the gate electrode GE in the thickness direction. The capacitor electrode CPE and the gate electrode GE may form an electrostatic capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 penetrates. The contact hole of the second interlayer insulating layer ILD2 may be connected to the contact hole of the first interlayer insulating layer ILD1 and the contact hole of the gate insulating layer GI.

The first connection electrode CNE1 may be arranged on the second interlayer insulating layer ILD2. The first connection electrode CNE1 may electrically connect the drain electrode DE of the thin-film transistor TFT and the second connection electrode CNE2. The first connection electrode CNE1 may be inserted into a contact hole formed in the second interlayer insulating layer ILD2, the first interlayer insulating layer ILD1, and the gate insulating layer GI to contact the drain electrode DE of the thin-film transistor TFT.

The first protective layer PVX1 may cover the first connection electrode CNE1 and the second interlayer insulating layer ILD2. The first protective layer PVX1 may protect the thin-film transistor TFT. The first protective layer PVX1 may include a contact hole through which the second connection electrode CNE2 penetrates.

The second connection electrode CNE2 may be arranged on the first protective layer PVX1. The second connection electrode CNE2 may electrically connect the first connection electrode CNE1 and the first pixel electrode AE1 of the first light emitting element ED1. The second connection electrode CNE2 may be inserted into a contact hole formed in the first protective layer PVX1 and may be in contact with the first connection electrode CNE1.

The second protective layer PVX2 may cover the second connection electrode CNE2 and the first protective layer PVX1. The second protective layer PVX2 may include a contact hole through which the first pixel electrode AE1 of the first light emitting element ED1 penetrates.

The bank layer BNK may be arranged on the second protective layer PVX2. The bank layer BNK may include a plurality of openings. The plurality of openings may penetrate the bank layer BNK to expose the second protective layer PVX2 but are not limited thereto. The second protective layer PVX2 may be referred to as a first via layer, and the bank layer BNK may be referred to as a second via layer. The first via layer and the second via layer may also be referred to collectively as the via layer. According to some embodiments, the first via layer and the second via layer may be replaced with a single via layer formed integrally. For example, one via layer may include a recess having a sloped surface by etching a portion thereof. The first pixel electrode AE1 described below may be formed to correspond to the recess.

The bank layer BNK has a sloped surface SSL1 defining a concave recess BNK-R downward. Further, the sloped surface SSL1 of the bank layer BNK may have a gentle slope with respect to the top surface of the bank layer BNK. An inner surface of the sloped surface SS of the bank layer BNK and an extension line of the bottom surface of the recess BNK-R have an inclined angle θ. The inclined angle θ may be an acute angle. The angle of inclination θ may range from 20 (or about 20) degrees to 70 (or about 70) degrees, for example, the angle of inclination θ may be 30 (or about 30) degrees but is not limited thereto. The recess BNK-R may have an upper width that is substantially wider than the lower width. In this way, the bank layer BNK may have a sloped structure defined by the recess BNK-R.

According to some embodiments, the bank layer BNK is illustrated as a single insulating film, but the bank layer BNK may be formed of a plurality of insulating films. For example, the bank layer BNK may include a first bank layer and a second bank layer. The second bank layer may be arranged on the first bank layer, and the second bank layer may have a recess exposing the first bank layer.

The bank layer BNK may be formed of an organic insulating material, such as an acrylic resin, an epoxy resin, a phenolic resin, a polyamide resin, a polyimide resin, or the like.

The light emitting element layer EML may be arranged on the thin-film transistor layer TFTL. The light emitting element layer EML may include a first light emitting element ED1, a pixel definition layer PDL, and a spacer SPC. According to some embodiments, the spacer SPC may be omitted.

The first light emitting element ED1 may include a first pixel electrode AE1, a first light emitting layer EL1, and a common electrode CE. The first pixel electrode AE1 may be arranged to overlap one of the recesses BNK-R defined by the bank layer BNK. The first pixel electrode AE1 is arranged along a sloped surface of the bank layer BNK. Thus, the first pixel electrode AE1 may have a sloped structure. The first pixel electrode AE1 may include an sloped portion AE1-S arranged on a sloped surface SSL1 of the recess BNK-R of the bank layer BNK, a bottom portion AE1-B connected to a bottom portion of the sloped portion AE1-S but extending in a direction away from the first light blocking area (or non-light emitting area), and an upper portion AE1-T connected to the upper portion of the sloped portion AE1-S and arranged on an upper portion of the bank layer BNK. The inclination angle of the sloped portion AE1-S of the first pixel electrode AE1 may be the same as the inclination angle of the sloped surface SSL1 of the bank layer BNK. For example, when the inclination angle of the sloped portion AE1-S is 20 to 70 degrees, the inclination angle of the sloped portion AE1-S of the first pixel electrode AE1 may also be 20 to 70 degrees. The first pixel electrode AE1 may have a concave shape. The sloped portion AE1-S surrounds the periphery of the bottom portion AE1-B, and the sloped portion AE1-S and the bottom portion AE1-B do not overlap in the third direction DR3, that is, the thickness direction. The bottom portion AE1-B and the upper portion AE1-T may be flat but may be formed to have a curvature during a process. The bottom portion AE1-B and the upper portion AE1-T may be formed relatively flat compared to the sloped portion AE1-S even though the bottom portion AE1-B and the upper portion AE1-T may be curved. The sloped portion AE1-S may be arranged on the outer edge of the bottom portion AE1-B.

The first pixel electrode AE1 may be electrically connected to the drain electrode DE of the thin-film transistor TFT through a first connection electrode CNE1 and a second connection electrode CNE2.

The pixel definition layer PDL may define a light emitting portion, and the areas or sizes thereof may be different from each other. The pixel definition layer PDL includes a plurality of openings. For example, in the first light emitting area EA1, the pixel definition layer PDL includes the first opening OA1. The pixel definition layer PDL may be arranged on a portion of the bank layer BNK and the first pixel electrode AE1. The upper portion AE1-T of the first pixel electrode AE1 may be covered at least in portion by the pixel definition layer PDL. Each opening of the pixel definition layer PDL may expose a portion of the first pixel electrode AE1. The first opening OA1 of the pixel definition layer PDL may expose the sloped portion AE1-S and the bottom portion AE1-B of the first pixel electrode AE1.

The pixel definition layer PDL may include a sloped portion PDLa having a sloped shape in an area adjacent to each opening, and a flat portion PDLb having a flat shape and arranged on one side of the sloped portion PDLa. For example, the sloped portion PDLa of the pixel definition layer PDL may be arranged on the outer side of the pixel definition layer PDL, and the flat portion PDLb may be arranged on the center of the pixel definition layer PDL.

The pixel definition layer PDL may separate and isolate adjacent pixel electrodes AE from each other. The pixel definition layer PDL may include a light absorbing material to prevent or reduce light reflection. For example, the pixel definition layer PDL may include a polyimide (PI)-based binder, and a pigment mixed with red, green, and blue. Alternatively, the pixel definition layer PDL may include a cardo-based binder resin and a mixture of a lactam-based black pigment and a blue pigment. Alternatively, the pixel definition layer PDL may include carbon black.

A spacer SPC may be arranged on a flat portion PDLb of the pixel definition layer PDL.

One side of the spacer SPC may be in contact with the pixel definition layer PDL, and the other side opposite to the one side may be in contact with the common electrode CE. The spacer SPC may maintain a gap between the pixel definition layer PDL and the common electrode CE. The spacer SPC may be made of an organic insulating material or an inorganic insulating material. For example, the spacer SPC may be made of an organic material such as a photoresist, a polyacrylic resin, a polyimide resin, an acrylic resin, or the like.

The first light emitting layer EL1 may be arranged on a portion of the first pixel electrode AE1 and the pixel definition layer PDL. For example, the first light emitting layer EL1 may be arranged on a first side of the first pixel electrode AE1 exposed by the first opening OA1 and on a portion of the sloped portion PDLa of the pixel definition layer PDL. The first light emitting layer EL1 is formed along the first pixel electrode AE1 on the first pixel electrode AE1 and thus may have a sloped structure. Accordingly, the region overlapping the sloped portion AE1-S of the first pixel electrode AE-1 in the third direction DR3, i.e., the thickness direction, is referred to as the sloped area, and the first light emitting layer EL1 arranged in the sloped area S-E becomes the sloped portion of the first light emitting layer EL1-S. The region overlapping the bottom portion AE1-B of the first pixel electrode AE-1 in the third direction DR3, i.e., the thickness direction, is referred to as a center area B-E because it includes the center of the light emitting area, and the first light emitting layer EL1 arranged in the center area B-E becomes a bottom portion EL1-B of the first light emitting layer EL1.

The first light emitting layer EL1 may be an organic light emitting layer made of an organic material. When the first light emitting layer EL1 corresponds to an organic light emitting layer, a thin-film transistor TFT applies a voltage (e.g., a set or predetermined voltage) to the first pixel electrode AE1 of the first light emitting element ED1. Further, the common electrode CE of the first light emitting element ED1 receives a common voltage or a cathode voltage, holes and electrons may move to the first light emitting layer EL1 through the hole transport layer and the electron transport layer, respectively, and the holes and electrons may combine with each other in the first light emitting layer EL1 to emit light.

The common electrode CE may be arranged on the first light emitting layer EL1 in the first light emitting area PA1 and may be arranged on the first pixel definition layer PDL1 and the spacer SPC in the first light blocking area BA1. For example, the common electrode CE may be arranged on the first light emitting layer EL1 and the first pixel definition layer PDL1 and the spacer SPC where the first light emitting layer EL1 is not arranged. Furthermore, the common electrode CE may be formed on the entire display area DA as an electrode form common to all pixels without being divided into a plurality of pixels.

The common electrode CE may receive a common voltage or a low-potential voltage. When the first pixel electrode AE1 receives a voltage corresponding to a data voltage and the common electrode CE receives a low-potential voltage, a potential difference is formed between the first pixel electrode AE1 and the common electrode CE, thereby enabling the first light emitting layer EL1 to emit light. The first pixel electrode AE1 may be referred to as the first electrode and the common electrode CE may be referred to as the second electrode.

A thin-film encapsulation layer TFEL may be arranged on the common electrode CE covering a plurality of first light emitting elements ED1. According to some embodiments, the thin-film encapsulation layer TFEL may include at least one inorganic film and at least one organic film to prevent or reduce contaminants or foreign substances such as oxygen, moisture, or dust, entering into the light emitting element layer EML.

According to some embodiments, the thin-film encapsulation layer TFEL may include a first thin-film encapsulation layer TFE1, a second thin-film encapsulation layer TFE2, and a third thin-film encapsulation layer TFE3 that are sequentially laminated in a third direction DR3. The first thin-film encapsulation layer TFE1 and the third thin-film encapsulation layer TFE3 may be inorganic layers, and the second thin-film encapsulation layer TFE2 arranged between may be an organic layer.

The first thin-film encapsulation layer TFE1 and the third thin-film encapsulation layer TFE3 may each include one or more inorganic insulators. According to some embodiments, the inorganic insulator may include aluminum oxide, titanium oxide, tantalum oxide, hafnium oxide, zinc oxide, silicon oxide, silicon nitride, and/or silicon oxynitride.

The second thin-film encapsulation layer TFE2 may include a polymer-based material. The polymer-based material may include an acrylic resin, an epoxy resin, polyimide, and polyethylene. For example, the second thin-film encapsulation layer TFE2 may include an acrylic-based resin, such as polymethylmethacrylate, polyacrylic acid, or the like. The second thin-film encapsulation layer TFE2 may be formed by curing a monomer or applying a polymer.

The thickness of the thin-film encapsulation layer TFEL may be 6.0 (or about 6.0) micrometers (μm) to 7.0 (or about 7.0) μm, and in one example, may be 6.9 (or about 6.9) μm, but embodiments according to the present disclosure are not limited thereto. The thickness of the thin-film encapsulation layer TFEL may be the longest distance (or height in the third direction DR3) among the distances (or heights in the third direction DR3) between the common electrode CE and the first overcoat layer OC1.

A first overcoat layer OC1 may be arranged on the third thin-film encapsulation layer TFE3. The first overcoat layer OC1 may have a relatively lower dielectric constant than the second thin-film encapsulation layer TFE2 to increase the sensitivity of the touch electrode layer TSL described later. For example, the dielectric constant of the first overcoat layer OC1 may be 2 F/m but embodiments according to the present disclosure are not limited thereto.

A touch electrode layer TSL may be arranged on the first overcoat layer OC1. The touch electrode layer TSL may include a touch insulation layer TIL and a touch electrode TE.

The touch electrode TE may include a driving electrode and a sensing electrode. The touch electrode TE may not overlap each light emitting area. The driving electrode and the sensing electrode may each be formed as a monolayer of molybdenum (Mo), titanium (Ti), copper (Cu), aluminum (Al), indium tin oxide (ITO), or a laminated structure of aluminum and titanium (Ti/Al/Ti), a laminated structure of aluminum and ITO (ITO/Al/ITO), an APC alloy, and a laminated structure of APC alloy and ITO (ITO/APC/ITO). The touch insulation layer TIL may include an inorganic and/or organic film and may cover the touch electrode TE.

The touch insulating layer TIL may have insulating and optical functions, and may include a light transmitting inorganic film including, for example, at least one of a silicon nitride layer, a silicon oxynitride layer, a silicon oxide layer, a titanium oxide layer, or an aluminum oxide layer. According to some embodiments, the touch electrode layer TSL may be omitted.

The thickness of the touch insulating layer TIL in the third direction DR3 may be 0.2 to 0.5 (or about 0.2 to 0.5) μm, and according to some embodiments, may be 0.3 (or about 0.3) μm.

The light control layer CFL may be arranged on the touch insulating layer TIL. The light control layer CFL may be arranged on a thin-film encapsulation layer TFEL in a structure where the touch insulating layer TIL is omitted.

The light control layer CFL may include a color filter CF, a multi-lens pattern MLP, and a light blocking pattern BM. The light blocking pattern BM is arranged in the first light blocking pattern BA1 and may overlap the pixel definition layer PDL in the third direction DR3, i.e., the thickness direction. The third direction DR3 is a direction perpendicular to the substrate. The light blocking pattern BM may be located on the touch insulating layer TIL. The light blocking pattern BM may be arranged on the encapsulation layer TFEL and include openings OP2 each overlapping the light emitting areas EA1, EA2, and EA3. The area or size of each opening of the light blocking pattern BM may be larger than the area or size of the openings of the pixel definition layer PDL. In other words, the width w1 of the opening OP2 formed by the light blocking pattern BM may be larger than the width w0 of the opening OP1 formed by the pixel definition layer PDL. The thickness of the third direction DR3 of the light blocking pattern BM is 1.0 (or about 1.0) μm to 1.8 (or about 1.8) μm, and may be, for example, 1.5 (or about 1.5) μm.

The light blocking pattern BM may include a light-absorbing material. For example, the light blocking pattern BM may include an inorganic black pigment or an organic black pigment. The inorganic black pigment may be carbon black, and the organic black pigment may include at least one of lactam black, perylene black, or aniline black, but embodiments according to the present disclosure are not limited thereto. The light blocking pattern BM absorbs external light incident from the outside to prevent or reduce the external light being reflected and prevents or reduces visible light interfering with and mixing colors between the light emitting areas, thereby relatively improving the color reproducibility of the display device 10.

According to some embodiments, the first pixel definition layer PDL1 and the light blocking pattern BM may partially block light emitted from the light emitting element layer EML. Therefore, only light having an optical path that does not overlap with the first pixel definition layer PDL1 and the light blocking pattern BM may be emitted to the outside of the display device 10.

The multi-lens pattern MLP may have one or more lens shapes that are convex upward. The multi-lens pattern MLP may change the direction of incident light to relatively improve LvA (the ratio of frontal light emission efficiency to side light emission efficiency).

The multi-lens pattern MLP overlaps the sloped portion AE1-S of the first pixel electrode AE1 in the third direction DR3, i.e., the thickness direction. The multi-lens pattern MLP does not overlap the bottom portion AE1-B of the first pixel electrode AE1 in the third direction DR3, i.e., the thickness direction.

According to some embodiments, the light control layer CFL may include a plurality of color filters CF1, CF2, and CF3. The plurality of color filters may be arranged on the light blocking pattern BM and the touch insulation layer TIL. Different color filters may be arranged corresponding to different light emitting areas, respectively. For example, the first color filter CF1 may be arranged corresponding to the first light emitting area EA1, the second color filter may be arranged corresponding to the second light emitting area, and the third color filter may be arranged corresponding to the third light emitting area. According to some embodiments, the first color filter CF1 may selectively transmit light of a specific color and block or absorb light of a specific color. For example, if the first color filter CF1 is a red color filter, it may transmit red light and block or transmit blue and green light but embodiments according to the present disclosure are not limited thereto. Each of the color filters may be arranged to have a larger area on the plan view than the openings of the light blocking pattern BM, and some may be arranged directly on the light blocking pattern BM.

The second overcoat layer OC2 may be arranged on the light control layer CFL. The second overcoat layer OC2 may be a colorless, light transmitting layer that does not have a color in the visible light band. For example, the second overcoat layer OC2 may include a colorless, light-transmitting organic material such as an acrylic resin.

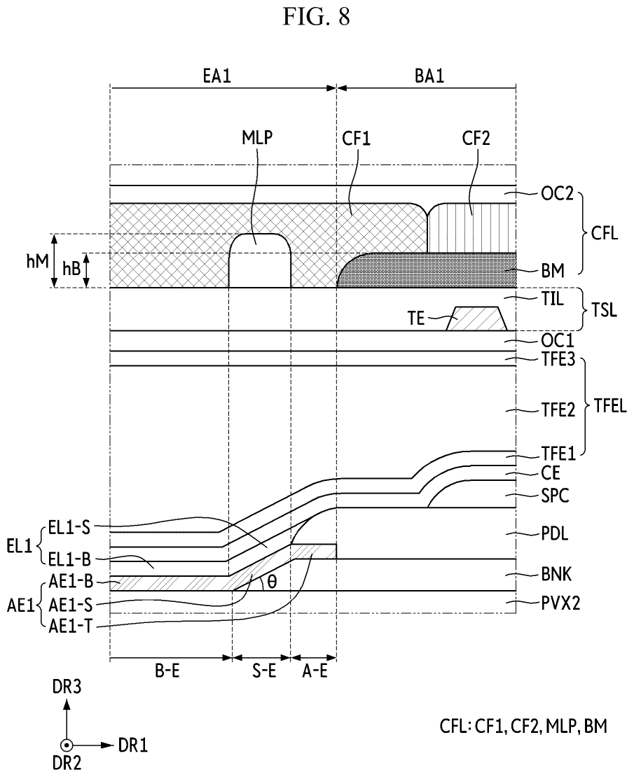

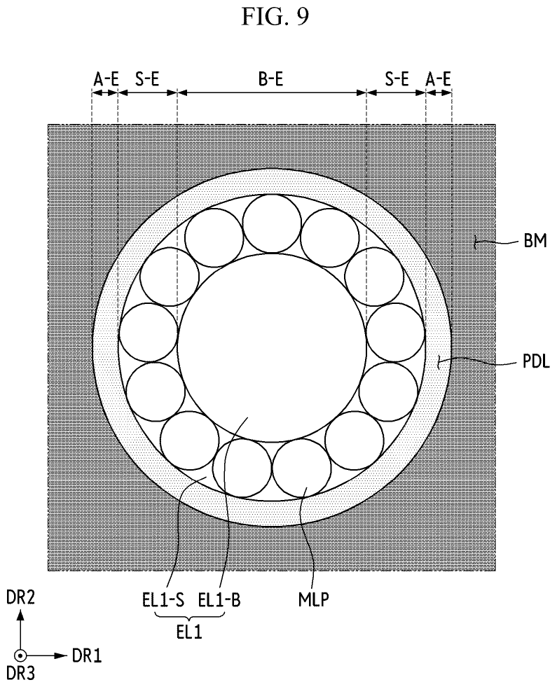

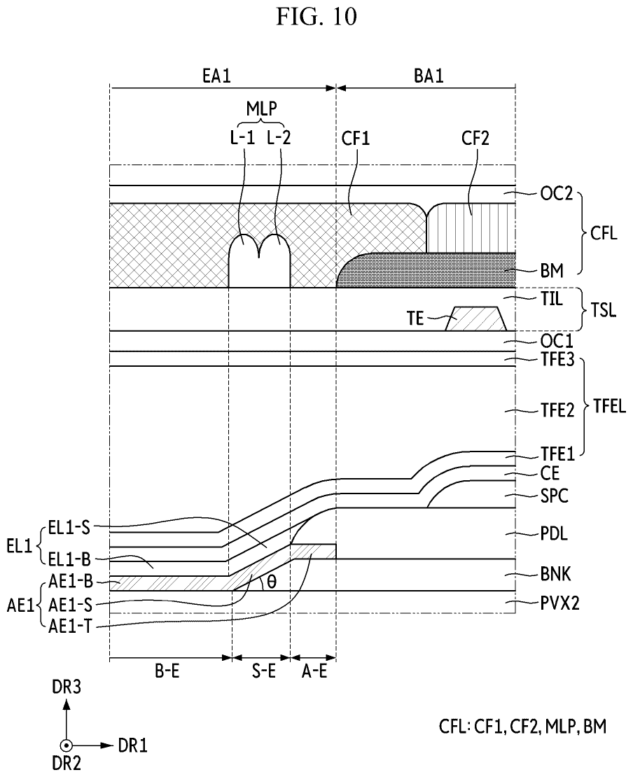

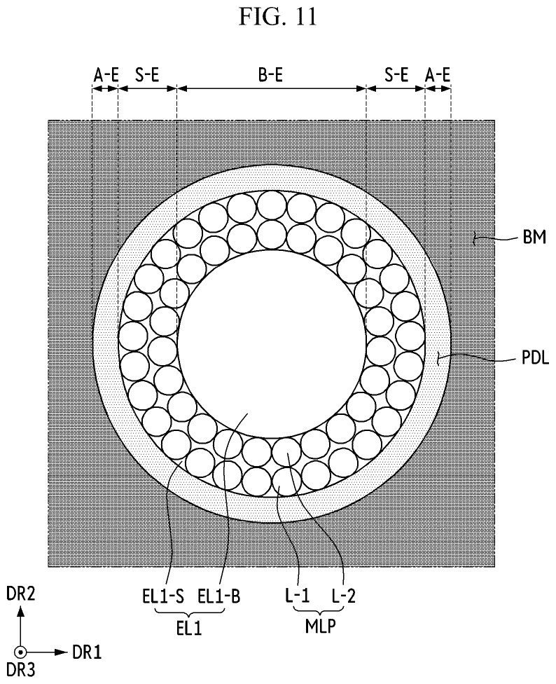

FIG. 8 is an enlarged view of area A of FIG. 7. FIG. 9 is a cross-sectional view illustrating the arrangement of components adjacent to the lens pattern of FIG. 8. FIG. 10 is an enlarged view of area A of FIG. 7 according to some embodiments. FIG. 11 is a cross-sectional view illustrating the arrangement of components adjacent to the lens pattern of FIG. 10.

Referring to FIGS. 8 and 9, a multi-lens pattern MLP may be arranged within a light control layer CFL together with a light blocking pattern BM. A color filter may cover the multi-lens pattern MLP and the light blocking pattern BM.

The multi-lens pattern MLP is arranged in an emitting area, and the light blocking pattern BM is arranged in a non-emitting area. According to some embodiments, the multi-lens pattern MLP may be arranged in a sloped area S-E to overlap with a sloped portion EL-S of the first emitting layer EL1 in the third direction DR3, i.e., the thickness direction.

The multi-lens pattern MLP may include a plurality of lenses whose top surfaces are convex upward. For example, one surface of the multi-lens pattern MLP is arranged on a touch electrode layer TSL, and the other surface opposite to the one surface has a lens shape that is convex upward. The multi-lens pattern MLP may have a plurality of multi-lenses arranged on the sloped area S-E surrounding the bottom area EL-B of the first light emitting layer EL1 on a plane. Thus, the plurality of multi-lenses of the multi-lens pattern MLP may be arranged to surround the bottom area EL-B on a plane.

Further, according to some embodiments, the multi-lens pattern MLP may not overlap the pixel definition layer PDL in the third direction DR3, i.e., the thickness direction.

The multi-lens pattern MLP may be formed thicker than the light blocking pattern BM. Because the multi-lens pattern MLP and the light blocking pattern BM are formed on the same plane (e.g., a touch electrode layer TSL), the multi-lens pattern MLP is formed higher than the light blocking pattern BM. The height from one side of the multi-lens pattern MLP to the top may be higher than the height from one side of the light blocking pattern BM to the top. For example, the thickness (or height (hM)) of the multi-lens pattern may be in a range of 1.6 (or about 1.6) μm or more and 2.0 (or about 2.0) μm or less. Further, the thickness (or height (hB)) of the light blocking pattern BM may be 1.5 (or about 1.5) μm or less.

The thickness of the multi-lens pattern MLP may be thinner than the thickness of the color filters CF1 and CF2.

The first color filter CF1 covers the opening defined by the light blocking pattern BM. Therefore, the first color filter CF1 completely covers the multi-lens pattern MLP arranged within the opening. The first color filter CF1 may cover the entire first light emitting area EA1 and may be arranged in a portion of the first light blocking pattern BA1. The multi-lens pattern MLP may be arranged within the first color filter CF1.

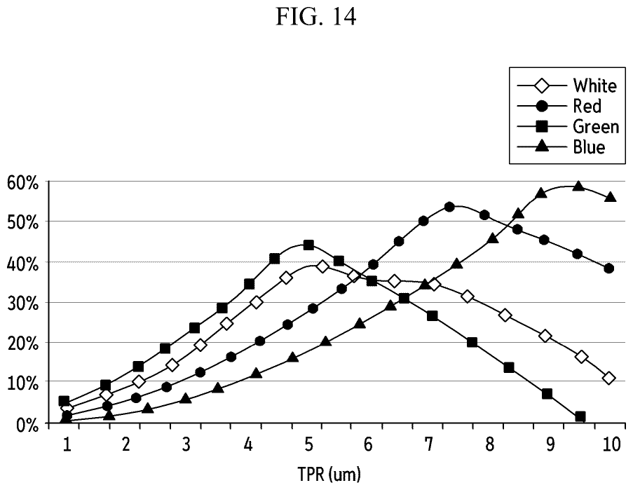

According to some embodiments, by arranging the multi-lens pattern MLP within the color filter, a separate layer for forming the multi-lens pattern MLP does not need to be arranged. Therefore, the thickness of the display panel may not increase depending on the thickness of the multi-lens pattern MLP. In general, the thicker the thickness of the MLP, the better the effective viewing angle improvement. This will be described later with reference to FIG. 14.

The multi-lens pattern MLP may be a lens for scattering light.

The multi-lens pattern MLP may include an organic material having a low refractive index and light transmittance. The refractive index of the multi-lens pattern MLP may be 1.5 (or about 1.5) or less, but embodiments according to the present disclosure are not limited thereto, and may vary depending on the refractive index of the light control layer CFL. The refractive index of the touch electrode layer TSL is 1.89 (or about 1.89) μm, which is a high refractive layer compared to the multi-lens pattern MLP. On the other hand, the refractive index of the light control layer CFL may be 1.6 (or about 1.6), which is higher than the refractive index of the multi-lens pattern MLP and lower than the refractive index of the touch electrode layer TSL.

The refractive direction of light may be changed by forming the multi-lens pattern MLP with a low refractive index.

Referring to FIGS. 10 and 11, the multi-lens pattern MLP may include a plurality of lens sections arranged in a sloped area S-E on a plane and surrounding a central area B-E. For example, the multi-lens pattern MLP may include a first lens section L-1 arranged adjacent to the central area B-E and including a plurality of lenses arranged on a first outer periphery surrounding the central area B-E, and a second lens section L-2 including a plurality of lenses arranged on a second outer periphery surrounding the first lens portion L-1. For example, the centers of each of the plurality of lenses included in the first lens unit L-1 may all be arranged on the first outer periphery. Also, the centers of each of the plurality of lenses included in the second lens portion L-2 may all be arranged on the second outer periphery.

Each of the plurality of lenses included in the first lens portion L-1 has a first curvature. Each of the plurality of lenses included in the second lens portion L-2 has a second curvature. The first curvature of the plurality of lenses included in the first lens portion L-1 and the second curvature of the plurality of lenses included in the second lens portion L-2 may be the same. In another modified example, the second curvature may be greater than the first curvature.

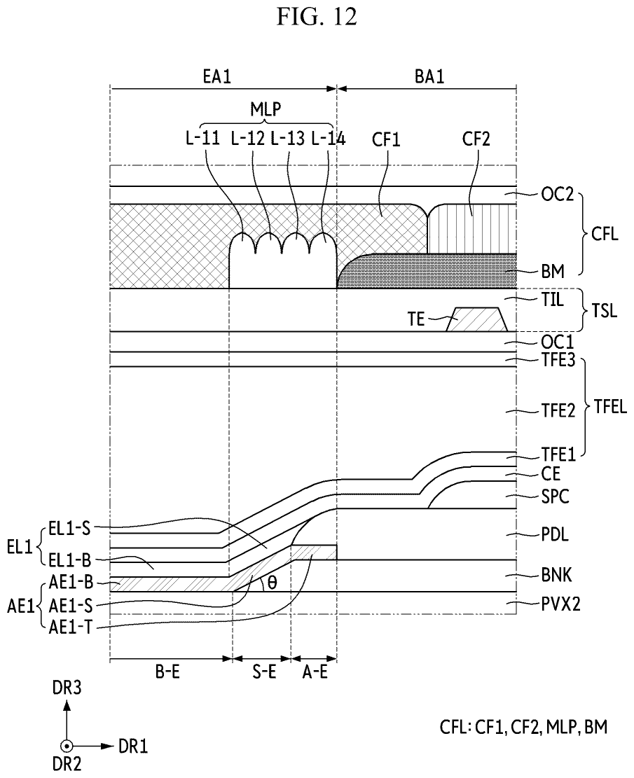

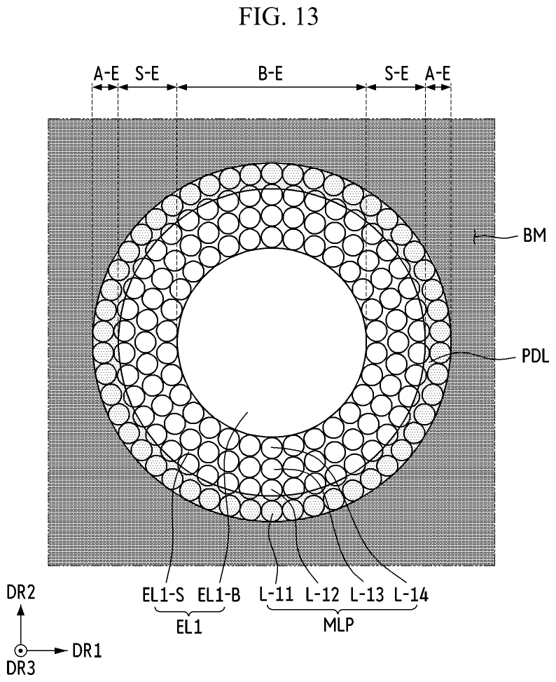

FIG. 12 is an enlarged view of area A of FIG. 7 according to some embodiments. FIG. 13 is a cross-sectional view illustrating the arrangement of components adjacent to the lens pattern of FIG. 10.

FIG. 12 and FIG. 13 are different from FIG. 10 and FIG. 11 in that the multi-lens pattern MLP is also arranged in an outer area A-E. The outer area A-E is an area that overlaps the pixel definition layer PDL in the third direction DR3, i.e., the thickness direction, and does not overlap the light blocking pattern BM. Hereinafter, referring to FIG. 12 and FIG. 13, the description overlapping with FIG. 7 to FIG. 11 will not be repeated, and the differences from FIG. 10 and FIG. 11 will be mainly described.

Referring to FIG. 12 and FIG. 13, the multi-lens pattern MLP overlaps the sloped area S-E and the outer area A-E. The multi-lens pattern MLP does not overlap the center area B-E.

The multi-lens pattern MLP is arranged in the sloped area S-E and the outer area A-E and may include a plurality of lens portions surrounding the center area B-E. For example, the multi-lens pattern MLP may include a first lens portion L-11 arranged adjacent to the central area B-E and including a plurality of lenses arranged on a first outer periphery surrounding the central area B-E, and a second lens portion L-21 including a plurality of lenses arranged on a second outer periphery surrounding the first lens portion L-11, a third lens portion L-31 including a plurality of lenses arranged on a third outer periphery surrounding the second lens portion L-21, and a fourth lens portion L-41 including a plurality of lenses arranged on a fourth outer periphery surrounding the third lens portion L-31. The first lens portion L-11 and the second lens portion L-21 may be arranged in a sloped area S-E, and the third lens portion L-31 and the fourth lens portion L-41 may be arranged in the outer area A-E.

Each of the plurality of lenses included in the first lens portion L-1 has a first curvature. Each of the plurality of lenses included in the second lens portion L-2 may have a second curvature, each of the plurality of lenses included in the third lens portion L-31 may have a third curvature, and each of the plurality of lenses included in the fourth lens portion L-41 may have a fourth curvature. The first curvature, the second curvature, the third curvature, and the fourth curvature may all be the same. The curvature of each lens portion may become greater from the center to the outside. For example, the second curvature may be greater than the first curvature, the third curvature may be greater than the second curvature, and the fourth curvature may be greater than the third curvature.

FIG. 14 is a graph to illustrate light refraction characteristics as a function of lens thickness.

The horizontal axis of FIG. 14 represents the thickness TPR of the lens, and the vertical axis represents the refractive characteristics of light. The side light emission efficiency increases compared to the front light emission efficiency as the lens thickness changes from 1 μm to 5 μm.

As the refractive properties of light increase, the viewing angle characteristics may be relatively improved.

Therefore, the thickness of the multi-lens pattern may be 1.6 (or about 1.6) μm or more and lower than the thickness of the color filter.

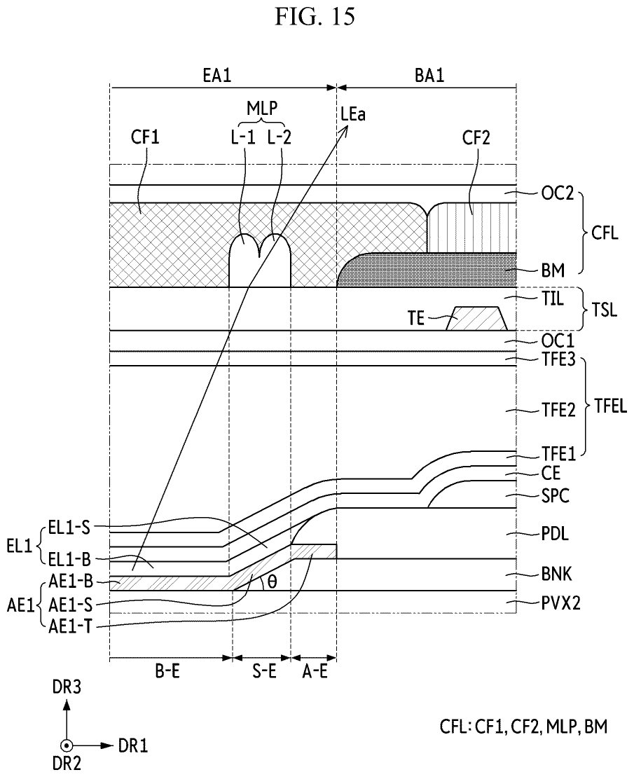

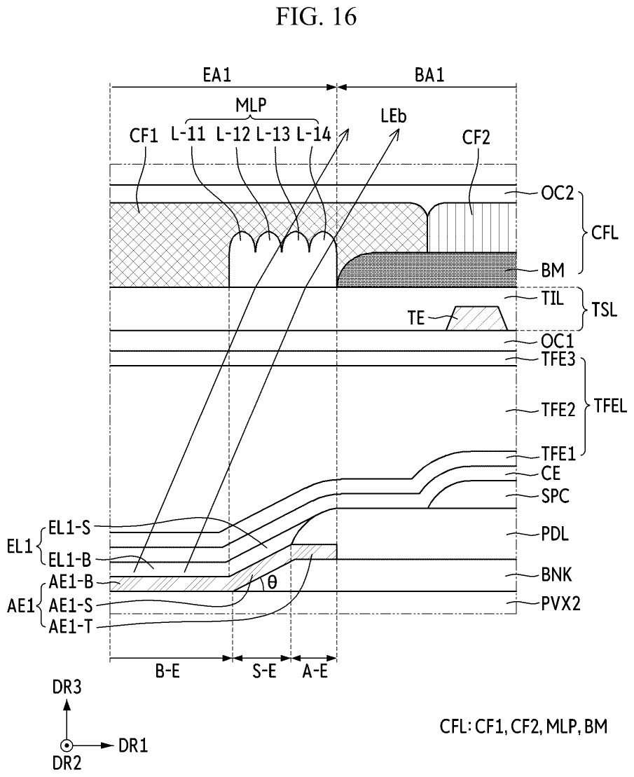

FIG. 15 is a conceptual diagram to illustrate the effect of relatively improving LvA (the ratio of side light emission efficiency to front light emission efficiency) in the embodiments of FIG. 10. FIG. 16 is a conceptual diagram to illustrate the effect of relatively improving LvA (the ratio of side light emission efficiency to front light emission efficiency) in the embodiments of FIG. 12.

Referring to FIGS. 15 and 16, light may be emitted from the bottom portion EL1-B of the first light emitting layer EL1 toward the front or the side. For example, light Lea and LEb having an oblique propagation path in the third direction DR3 may be emitted from the bottom portion EL1-B of the first light emitting layer EL1. The light LEa, and LEb may be emitted from the bottom portion EL1-B of the first light emitting layer EL1 and may transmit through the multi-lens pattern MLP. The light Lea and LEb emitted from the bottom portion EL1-B of the first light emitting layer EL1 may be refracted and propagated further outward than the propagation direction by passing through the multi-lens pattern MLP having a low refractive index. As a result, the brightness of light emitted toward the side of the display device 10 may be increased, thereby relatively improving side visibility.

According to some embodiments, when the multi-lens pattern MLP is employed as a scattering lens, the multi-lens pattern MLP may relatively improve visibility by scattering light passing through the multi-lens pattern MLP. The scattering lens may have the effect of scattering the light passing through by including a scattering body inside the multi-lens pattern MLP or roughening the surface. Even when the multi-lens pattern MLP is employed as a scattering lens in this way, the side visibility may be relatively improved.

On the other hand, because the path of light spreads further outward from the light emitting area (EA1, EA2, EA3 in FIGS. 6 and 7) as it goes toward one side of the third direction DR3, extending the multi-lens pattern MLP to the outer area A-E may be more advantageous for relatively improving the side visibility when the distance from the first light emitting layer EL1 to the multi-lens pattern MLP is relatively far.

Hereinafter, a process for manufacturing a display device according to some embodiments will be described in more detail.

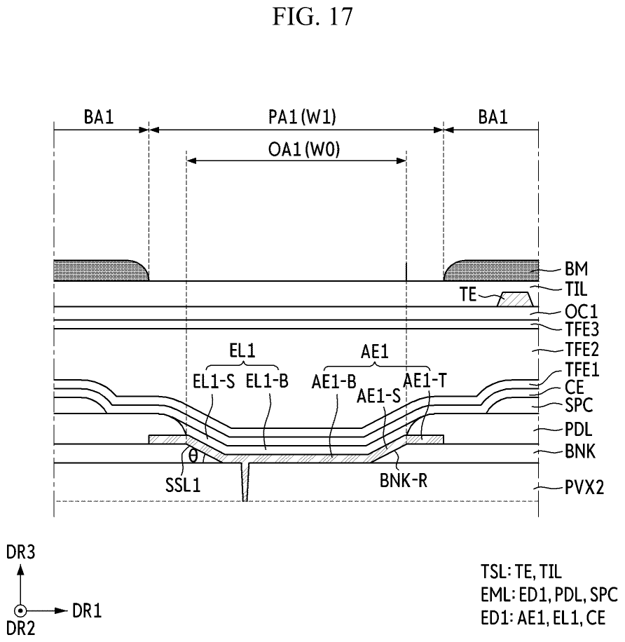

FIGS. 17 to 19 are cross-sectional views to illustrate a process for manufacturing a display device according to some embodiments.

First, referring to FIG. 17, a light blocking pattern BM is formed on the touch electrode layer TSL.

The process of forming the light blocking pattern BM may be performed by, for example, a printing method such as offset, gravure, or screen printing, or the like, or by forming a photoresist pattern PR but embodiments according to the present disclosure are not limited thereto.

In the process of forming the light blocking pattern BM an opening defined by the light blocking pattern BM is formed. To secure light efficiency and side visibility, the area of the light blocking pattern BM should be expanded so as not to exceed the path of light so as not to obstruct the path of light emitted from the first light emitting layer EL1 of the sloped area S-E without being shading by the pixel definition layer PDL.

In this case, because the path of light emitted from the first light emitting layer EL1 of the sloped area S-E spreads further outward from the light emitting area EA1, EA2, and EA3 as it moves away from the substrate in the third direction DR3, the width of the opening of the light blocking pattern BM should be formed wider than the width of the opening of the pixel definition layer PDL. In other words, the opening formed by the light blocking pattern BM completely overlaps the light emitting area EA, and the width w1 of the opening formed by the light blocking pattern BM may be substantially the same as the light emitting area EA.

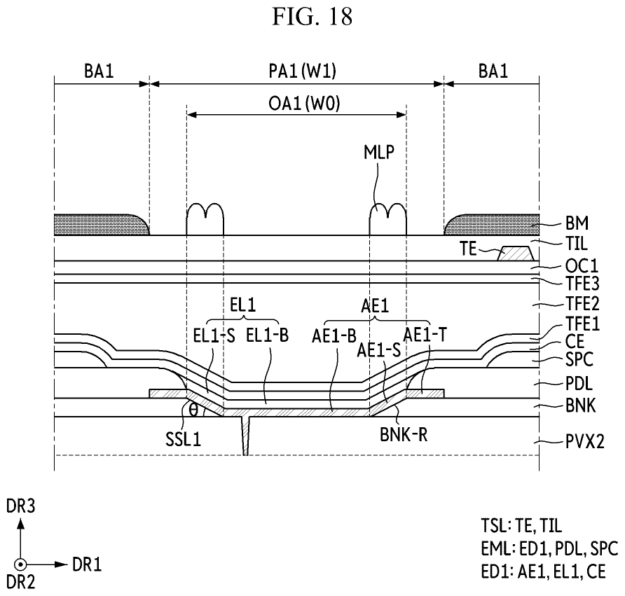

Referring to FIG. 18, a multi-lens pattern MLP may be formed on the touch electrode layer TSL.

The multi-lens pattern MLP may be formed using a photoresist pattern PR. The process of forming a photoresist pattern PR on a touch electrode layer TSL may be formed, for example, by forming an organic material layer having a low refractive index and light transmittance, forming a photosensitive organic material used as a mask, and then developing and exposing. After the exposure is complete, the photoresist pattern PR may be removed by ashing.

As described with reference to FIGS. 8 and 10, the multi-lens pattern MLP may include a plurality of lenses having a curvature in an upwardly convex shape. As described with reference to FIGS. 8 and 10, the multi-lens pattern MLP

may be formed to be arranged only in the sloped area S-E and may be formed to be arranged in the sloped area S-E and the outer area A-E as shown in FIG. 12.

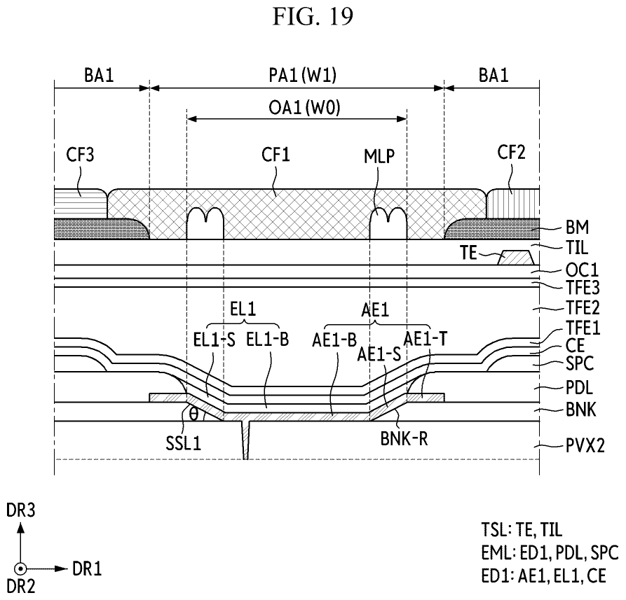

Referring to FIG. 19, the first color filter CF1 may be formed to cover an opening defined by a light blocking pattern BM and cover at least a portion of the light blocking pattern BM. Accordingly, the area of the first color filter CF1 may be larger than the area of the first light emitting area EA1. The first color filter CF1 may completely cover the first light emitting area EA1. Further, because the multi-lens pattern MLP is arranged within the opening defined by the light blocking pattern BM, the first color filter CF1 is formed to completely cover the multi-lens pattern MLP.

The method of forming the first color filter CF1 may use a deposition process or may employ a sputtering process or a printing technology but embodiments according to the present disclosure are not limited thereto.

The display device according to some embodiments may be applied to various electronic devices. The electronic device according to some embodiments includes the display device described above and may further include a module or device having additional functions in addition to the display device.

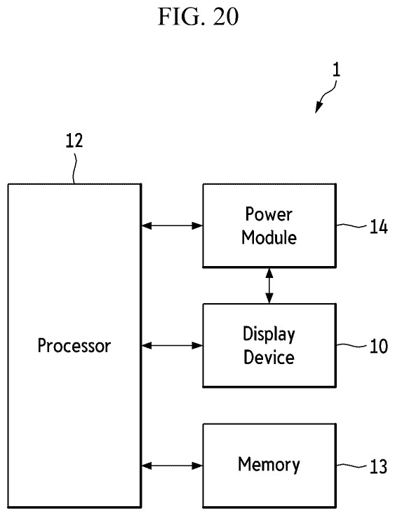

FIG. 20 is a block diagram of an electronic device according to some embodiments of the present disclosure. Referring to FIG. 20, the electronic device 1 according to some embodiments of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to some embodiments of the present disclosure may be included in the display device 10 according to some embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

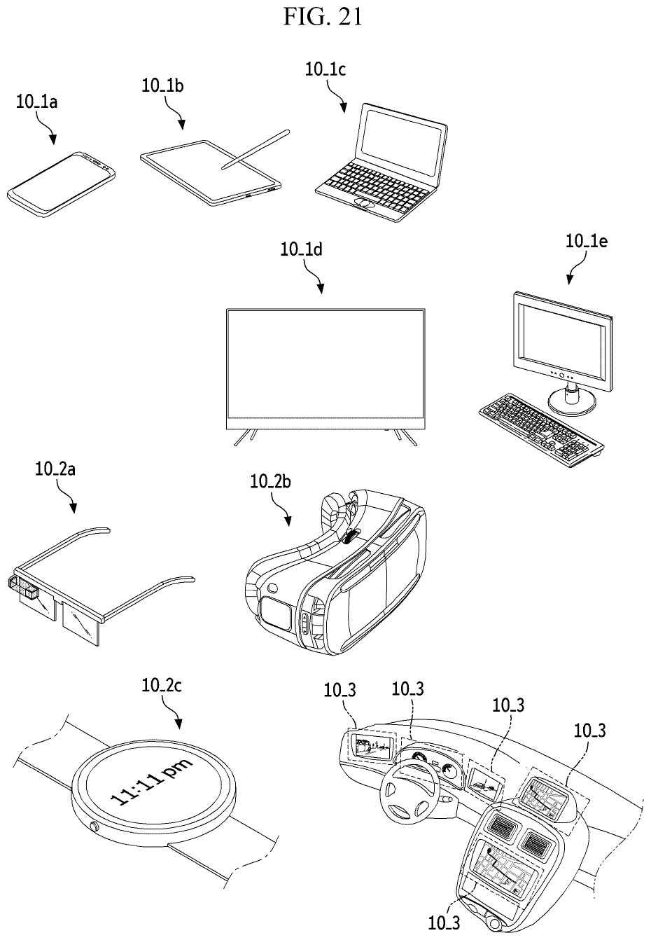

FIG. 21 is a schematic diagram of an electronic device according to various embodiments of the present disclosure.

Referring to FIG. 21, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

It should be understood, however, that the aspects and features of embodiments of the present disclosure are not restricted to those specifically set forth herein. The above and other aspects of embodiments according to the present disclosure will become more apparent to one of ordinary skill in the art to which the present disclosure pertains by referencing the claims, with equivalents thereof to be included therein.

What is claimed is:

1. A display device comprising:
a substrate;
a first electrode on the substrate, including a sloped portion and a bottom portion connected from the sloped portion;
a pixel definition layer on the substrate and having a first opening exposing the sloped portion and the bottom portion of the first electrode;
a light emitting layer on the first electrode exposed through the first opening;
a second electrode on the light emitting layer;
an encapsulation layer on the second electrode; and
a light control layer on the encapsulation layer and including a color filter, a multi-lens pattern, and a light blocking pattern,
wherein the multi-lens pattern overlaps the sloped portion in a direction perpendicular to the substrate,
wherein the light blocking pattern overlaps the pixel definition layer in a direction perpendicular to the substrate,
wherein the multi-lens pattern is within the color filter.

2. The display device of claim 1, wherein a thickness of the multi-lens pattern is thicker than a thickness of the light blocking pattern and thinner than a thickness of the color filter.

3. The display device of claim 1, wherein a refractive index of the multi-lens pattern is lower than a refractive index of the encapsulation layer and lower than a refractive index of the color filter.

4. The display device of claim 3, wherein the refractive index of the multi-lens pattern is 1.5 or less.

5. The display device of claim 1, wherein the multi-lens pattern includes a plurality of lenses having a shape in which the top surface is convex upward.

6. The display device of claim 5, wherein the multi-lens pattern includes a first lens portion including a plurality of lenses having a center at a first outer periphery, and a second lens portion including a plurality of lenses having a center at a second outer periphery,
wherein the first outer periphery and the second outer periphery are concentric outer peripheries, and a diameter of the second outer periphery is larger than a diameter of the first outer periphery.

7. The display device of claim 6, wherein the first lens portion surrounds the bottom portion on a plane, and
wherein the second lens portion surrounds the first lens portion on a plane.

8. The display device of claim 1, wherein each of the plurality of lenses included in the first lens portion has a first curvature, and each of the plurality of lenses included in the second lens portion has a second curvature,
wherein the first curvature and the second curvature are different.

9. The display device of claim 1, wherein the multi-lens pattern is further arranged in an outer area,
wherein the outer area overlaps the pixel definition layer in a direction perpendicular to the substrate but does not overlap the light blocking pattern and the sloped portion.

10. The display device of claim 9, wherein the multi-lens pattern comprises,
a first lens portion including a plurality of lenses that overlap with a sloped portion of the first electrode in a direction perpendicular to the substrate and surround the bottom portion,
a second lens portion including a plurality of lenses that overlap with a sloped portion of the first electrode in a direction perpendicular to the substrate and surround the first lens portion,
and a third lens portion including a plurality of lenses that are at least partially in the outer area and surround the second lens portion.

11. The display device of claim 1, wherein the light blocking pattern has a second opening having a width greater than a width of the first opening and overlapping the first opening,
wherein the multi-lens pattern is in the second opening,
wherein the color filter covers the multi-lens pattern and the second opening.

12. The display device of claim 1, further comprising a first overcoat layer between the encapsulation layer and the light control layer; and
a touch electrode layer between the first overcoat layer and the light control layer,
wherein the touch electrode layer includes a touch electrode,
wherein the touch electrode overlaps the light blocking pattern in a direction perpendicular to the substrate.

13. The display device of claim 1, wherein the pixel definition layer includes a light blocking material.

14. The display device of claim 1, further comprising a via layer on the substrate,
wherein the via layer includes a first via layer having a sloped corresponding to a sloped of the first electrode, and a second via layer below the first via layer and including a surface corresponding to a bottom portion of the first electrode.

15. The display device of claim 14, wherein the first via layer and the second via layer are different layers, or
wherein the first via layer and the second via layer are a single via layer formed integrally.

16. A display device comprising:
a substrate;
a first electrode on the substrate, including a sloped portion and a bottom portion connected from the sloped portion;
a pixel definition layer on the substrate and having a first opening exposing the sloped portion and the bottom portion of the first electrode;
a light emitting layer on the first electrode exposed through the first opening;
a second electrode on the light emitting layer;
an encapsulation layer on the second electrode; and
a light control layer on the encapsulation layer and including a color filter, a multi-lens pattern, and a light blocking pattern,
wherein the multi-lens pattern includes a plurality of lenses that are convex upward and surrounds the bottom portion on a plane,
wherein the light blocking pattern surrounds the multi-lens pattern on the same plane as the multi-lens pattern,
wherein the color filter covers the multi-lens pattern.

17. The display device of claim 16, wherein a thickness of the multi-lens pattern is thicker than a thickness of the light blocking pattern and thinner than a thickness of the color filter.

18. The display device of claim 15, wherein a refractive index of the multi-lens pattern is lower than a refractive index of the encapsulation layer and a refractive index of the color filter,
wherein the refractive index of the multi-lens pattern is 1.5 or less.

19. The display device of claim 15, further comprising a first overcoat layer on the encapsulation layer; and
a touch electrode layer on the first overcoat layer,
wherein the touch electrode layer includes a touch electrode, and wherein the touch electrode overlaps the light blocking pattern.

20. A display device comprising:
as an electronic device,
a display panel configured to display an image,
wherein the display panel includes,
a substrate;
a first electrode on the substrate, including a sloped portion and a bottom portion connected from the sloped portion;
a pixel definition layer on the substrate and having a first opening exposing the sloped portion and the bottom portion of the first electrode;
a light emitting layer on the first electrode exposed through the first opening;
a second electrode on the light emitting layer;
an encapsulation layer on the second electrode; and
a light control layer on the encapsulation layer and including a color filter, a multi-lens pattern, and a light blocking pattern,
wherein the multi-lens pattern overlaps the sloped portion in a direction perpendicular to the substrate, and wherein the light blocking pattern overlaps the pixel definition layer in a direction perpendicular to the substrate,
wherein the multi-lens pattern is within the color filter.
